(19) United States
(12) Patent Application Publication
(10) Pub. No.: US 2020/0083875 A1
(43) Pub. Date: Mar. 12, 2020

(54) MASTER READ FROM SLAVE OVER PULSE-WIDTH MODULATED HALF-DUPLEX 1-WIRE BUS

(71) Applicant: QUALCOMM Incorporated, San Diego, CA (US)

(72) Inventors: Lalan Jee MISHRA, San Diego, CA (US); Richard Dominic WIETFELDT, San Diego, CA (US)

(21) Appl. No.: 16/556,835

(22) Filed: Aug. 30, 2019

Related U.S. Application Data
(60) Provisional application No. 62/728,397, filed on Sep. 7, 2018.

(51) Int. Cl. H03K 7/08; H03K 3/0233; H03K 5/003

(52) U.S. Cl. CPC H03K 7/08; H03K 5/003; H03K 3/02332

(57) ABSTRACT

Systems, methods, and apparatus for one wire communication are disclosed. A method performed at a master device includes driving a wire coupling the master device to a slave device from a first voltage to a second voltage, causing a line driver in the master device to present a high impedance to the wire after the wire has been driven to the second voltage, determining that the slave device is communicating a first bit-value when the wire has been driven to the first voltage before a threshold time period has elapsed, determining that the slave device is communicating a second bit-value when the wire is at the second voltage after the threshold time period has elapsed, and driving the wire to transition from the second voltage to the first voltage when the wire is at the second voltage after the threshold time period has elapsed.

### PRIORITY

This application claims priority to and the benefit of U.S. Provisional Patent Application Ser. No. 62/728,397 filed in the U.S. Patent Office on Sep. 7, 2018, the entire content of this application being incorporated herein by reference as if fully set forth below in its entirety and for all applicable purposes.

### TECHNICAL FIELD

The present disclosure relates generally to serial communication and, more particularly, to providing timing of read operations involving devices configured for one-wire communication through a Radio Frequency Front-End interface.

### BACKGROUND

Mobile communication devices may include a variety of components including circuit boards, integrated circuit (IC) devices and/or System-on-Chip (SoC) devices. The components may include processing circuits, user interface components, storage and other peripheral components that communicate through a serial bus. The serial bus may be operated in accordance with a standardized or proprietary protocol. In one example, a serial bus operated in accordance with an Inter-Integrated Circuit (I2C bus or I²C). The I2C bus was developed to connect low-speed peripherals to a processor, where the I2C bus is configured as a multi-drop bus. A two-wire I2C bus includes a Serial Data Line (SDA) that carries a data signal, and a Serial Clock Line (SCL) that carries a clock signal.

A serial bus may employ a multi-master protocol in which one or more devices can serve as a master and a slave for different messages transmitted on the serial bus. In one example, Improved Inter-Integrated Circuit (I3C) protocols may be used to control operations on a serial bus. I3C protocols are defined by the Mobile Industry Processor Interface (MIPI) Alliance and derive certain implementation aspects from the I2C protocol. Original implementations of the I2C protocol supported data signaling rates of up to 100 kilobits per second (100 kbps) in standard-mode operation, with more recent standards supporting speeds of 400 kbps in fast-mode operation, and 1 megabit per second (Mbps) in fast-mode plus operation.

In another example, the Radio Frequency Front-End (RFFE) interface defined by the MIPI Alliance provides a communication interface for controlling various radio frequency (RF) front-end devices, including power amplifier (PA), low-noise amplifiers (LNAs), antenna tuners, filters, sensors, power management devices, switches, etc. These devices may be collocated in a single IC device or provided in multiple IC devices. In a mobile communication device, multiple antennas and radio transceivers may support multiple concurrent RF links.

In another example, the system power management interface (SPMI) defined by the MIPI

Alliance provides a hardware interface that may be implemented between baseband or application processors and peripheral components. In some implementations, the SPMI is deployed to support power management operations within a device.

The use of MIPI-defined serial buses in place of parallel buses can reduce the number of physical general-purpose input/output (GPIO) pins required to support communication between multiple devices. As device complexity increases, demand for GPIO pins also increases and there is continual demand for simplified bus architectures.

### SUMMARY

Certain aspects of the disclosure relate to systems, apparatus, methods and techniques that can support communication with device interfaces that use a single-wire link. In some implementations, a bus master can provide timing information while reading from a slave device coupled to a single-wire serial bus.

In various aspects of the disclosure, a method performed at a master device coupled to a serial bus includes driving a wire coupling a master device to a slave device from a first voltage level to a second voltage level, causing a line driver in the master device to present a high impedance to the wire after the wire has been driven to the second voltage level, determining that the slave device is communicating a first bit-value when the wire has been driven to the first voltage level before a threshold duration of time has elapsed, determining that the slave device is communicating a second bit-value when the wire is at the second voltage level after the threshold duration of time has elapsed, and driving the wire to transition from the second voltage level to the first voltage level when the wire is at the second voltage level after the threshold duration of time has elapsed.

In one aspect, the wire is driven by the master device to the second voltage level as a bit transmission interval begins. In one aspect, the method includes coupling a first resistor to the wire prior to causing the line driver in the master device to present the high impedance to the wire. The first resistor may be configured to pull the wire to the second voltage level. In one aspect, a keeper circuit coupled to the wire is operable to hold the wire at the second voltage level after causing the line driver in the master device to present the high impedance to the wire. In one aspect, the method includes detecting that the wire has been driven to the first voltage level before the threshold duration of time has elapsed, and coupling a second resistor to the wire after detecting that the wire has been driven to the first voltage level before the threshold duration of time has elapsed. The second resistor may be configured to pull the wire to the first voltage level. In one aspect, a keeper circuit coupled to the wire is operable to hold the wire at the first voltage level after causing the line driver in the master device to present the high impedance to the wire. The master device and the slave device may be configured to use the wire to exchange data provided in accordance with a radio frequency front end protocol. The data is exchanged in a pulse width modulated signal transmitted over the wire.

In various aspects of the disclosure, a data communication apparatus has a line driver configured to couple the apparatus to a wire of a serial bus, and a protocol controller. The protocol controller may be configured to cause the line driver to drive the wire from a first voltage level to a second voltage level as a bit transmission interval begins, cause the line driver to present a high impedance to the wire after the wire has been driven to the second voltage level, determine that a slave device is communicating a first bit-value when the wire has been driven to the first voltage level before a threshold duration of time has elapsed, determine that the slave device is communicating a second bit-value when the wire is at the second voltage level after the threshold duration of time has elapsed, and cause the line driver to drive the wire to transition from the second voltage level to the first voltage level when the wire is at the second voltage level after the threshold duration of time has elapsed.

In various aspects of the disclosure, a method of data communication includes causing a line driver of a slave device to present a high impedance to a wire coupling a master device to a slave device, detecting that the wire has been driven from a first voltage level to a second voltage level, driving the wire to the first voltage level before a threshold duration of time has elapsed when a bit of data has a first value, and causing the line driver to present the high impedance to the wire after driving the wire to the first voltage level.

In one aspect, the wire is driven by the master device to the second voltage level as a bit transmission interval begins. In one aspect, a first resistor coupled to the wire holds the wire at the second voltage level after the wire is driven by the master device to the second voltage level. In one aspect, a keeper circuit coupled to the wire is operable to hold the wire at the second voltage level after the wire is driven by the master device to the second voltage level. In one aspect, a second resistor coupled to the wire holds the wire at the first voltage level after the wire is driven to the first voltage level. In one aspect, a keeper circuit coupled to the wire is operable to hold the wire at the first voltage level after the wire is driven to the first voltage level. The master device and the slave device may be configured to use the wire to exchange data provided in accordance with a radio frequency front end protocol. The data is exchanged in a pulse width modulated signal transmitted over the wire.

In various aspects of the disclosure, a data communication apparatus has a line driver configured to couple the apparatus to a wire of a serial bus, and a protocol controller. The protocol controller may be configured to cause a line driver of a slave device to present a high impedance to a wire coupling a master device to a slave device, detect that the wire has been driven from a first voltage level to a second voltage level, drive the wire to the first voltage level before a threshold duration of time has elapsed when a bit of data has a first value, and cause the line driver to present the high impedance to the wire after driving the wire to the first voltage level. The wire may be driven by the master device to the second voltage level as a bit transmission interval begins.

### BRIEF DESCRIPTION OF THE DRAWINGS

FIG. 1 illustrates an apparatus employing a data link between IC devices that is selectively operated according to one of plurality of available standards.

FIG. 2 illustrates a first example of an apparatus employing a data link that may be used to communicatively couple two or more devices.

FIG. 3 illustrates a second example of an apparatus employing data links that may be used to communicatively couple two or more devices, including various radio frequency front-end devices.

FIG. 4 illustrates a system in which one-wire slave devices are coupled to a 1-Wire serial bus in accordance with certain aspects disclosed herein.

FIG. 5 illustrates a system in which one-wire slave devices and two-wire slave devices are coupled to a common data wire of a serial bus in accordance with certain aspects disclosed herein.

FIG. 6 illustrates certain aspects of timing related to a master-originated pulse-width modulation slave read transaction provided in accordance with certain aspects disclosed herein.

FIG. 7 illustrates an example of line termination and keeper circuits that facilitate transmission of a master-originated pulse-width modulation slave read transaction in accordance with certain aspects disclosed herein.

FIG. 8 illustrates timing related to transmissions during one example of a master-originated pulse-width modulation slave read transaction provided in accordance with certain aspects disclosed herein.

FIG. 9 illustrates one example of an apparatus employing a processing circuit that may be adapted according to certain aspects disclosed herein.

FIG. 10 is a flowchart that illustrates a method for data communication at a master device in accordance with certain aspects disclosed herein.

FIG. 11 illustrates an example of a hardware implementation for a bus master apparatus adapted in accordance with certain aspects disclosed herein.

FIG. 12 is a flowchart that illustrates a method for data communication at a 1-Wire slave device in accordance with certain aspects disclosed herein.

FIG. 13 illustrates an example of a hardware implementation for a 1-Wire slave apparatus adapted in accordance with certain aspects disclosed herein.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

### Overview

Devices that include multiple SoC and other IC devices often employ a shared communication interface that may include a serial bus or other data communication link to connect processors with modems and other peripherals. The serial bus or other data communication link may be operated in accordance with multiple standards or protocols defined. For example, the serial bus may be operated in accordance with an I2C, I3C, SPMI, and/or RFFE protocol, or another protocol that may be configured for half-duplex operation. Increased functionality and complexity of operations involving devices coupled to serial buses, together with the imposition of more stringent timing constraints in support of applications, peripherals and sensors can result in greater demand on GPIO pins and communication link throughput.

Certain aspects of the disclosure relate to techniques for communication over a single wire, using pulse-width modulation (PWM) to combine clock and data in the same signal. In one aspect, a bus master may be adapted to communicate with some slave devices over a single wire (data only) and other devices over two wires (data and clock). The protocol controller may signal a type of (one-wire or two-wire) communication based on the configuration of a modified sequence start condition (SSC) used to initiate a transaction. Various aspects of the of the modified SSC may comply or be compatible with specifications for SSCs defined by RFFE protocols.

Certain aspects of the disclosure relate to the use of PWM for device read operations. In some systems, low-cost peripheral devices may have limited capabilities. For example, sensor devices that are designed for low-power operation may have limited or no internal timing references, and these devices may rely on timing provided by a bus master in a host device to transmit data over a serial bus that couples the host and peripheral devices. Conventionally, a peripheral device is required to have an internal timing reference when a one-wire bus is used. According to certain aspects of this disclosure, a master device can provide timing that enables a peripheral to communicate using PWM encoding.

In one example a one-wire master device has a line driver adapted to couple the master device to a wire of a serial bus, and a processor configured to cause the line driver to drive the wire from a first voltage level to a second voltage level as a bit transmission interval begins, cause the line driver to present a high impedance to the wire after the wire has been driven to the second voltage level, determine that a slave device is communicating a first bit-value when the wire has been driven to the first voltage level before a threshold duration of time has elapsed, determine that the slave device is communicating a second bit-value when the wire is at the second voltage level after the threshold duration of time has elapsed, and cause the line driver to drive the wire from the second voltage level to the first voltage level when the wire is at the second voltage level after the threshold duration of time has elapsed.

Certain aspects disclosed herein provide protocols that may replace or supplement a serial bus protocol, such as an I2C, I3C, SPMI, and/or RFFE protocol. Certain aspects are applicable to a serial bus operated in half-duplex mode or full-duplex mode. Certain aspects are applicable to point-to-point Universal Asynchronous Receiver/Transmitter (UART) interfaces, Line-Multiplexed UART (LM-UART) interfaces, or another type of point-to-point interface. In some implementations, certain aspects disclosed herein may be deployed to support exchange of virtual GPIO (VGI) messages, which can be used to communicate the state or change in state of physical GPIO pins without physical connections between devices. Certain aspects are applicable to multipoint interfaces, point-to-point interfaces, or interfaces switchable between point-to-point and multipoint modes.

### Examples Of Apparatus That Employ Serial Data Links

According to certain aspects of the disclosure, a serial data link may be used to interconnect electronic devices that are subcomponents of an apparatus such as a cellular phone, a smart phone, a session initiation protocol (SIP) phone, a laptop, a notebook, a netbook, a smartbook, a personal digital assistant (PDA), a satellite radio, a global positioning system (GPS) device, a smart home device, intelligent lighting, a multimedia device, a video device, a digital audio player (e.g., MP3 player), a camera, a game console, an entertainment device, a vehicle component, a wearable computing device (e.g., a smart watch, a health or fitness tracker, eyewear, etc.), an appliance, a sensor, a security device, a vending machine, a smart meter, a drone, a multicopter, or any other similar functioning device.

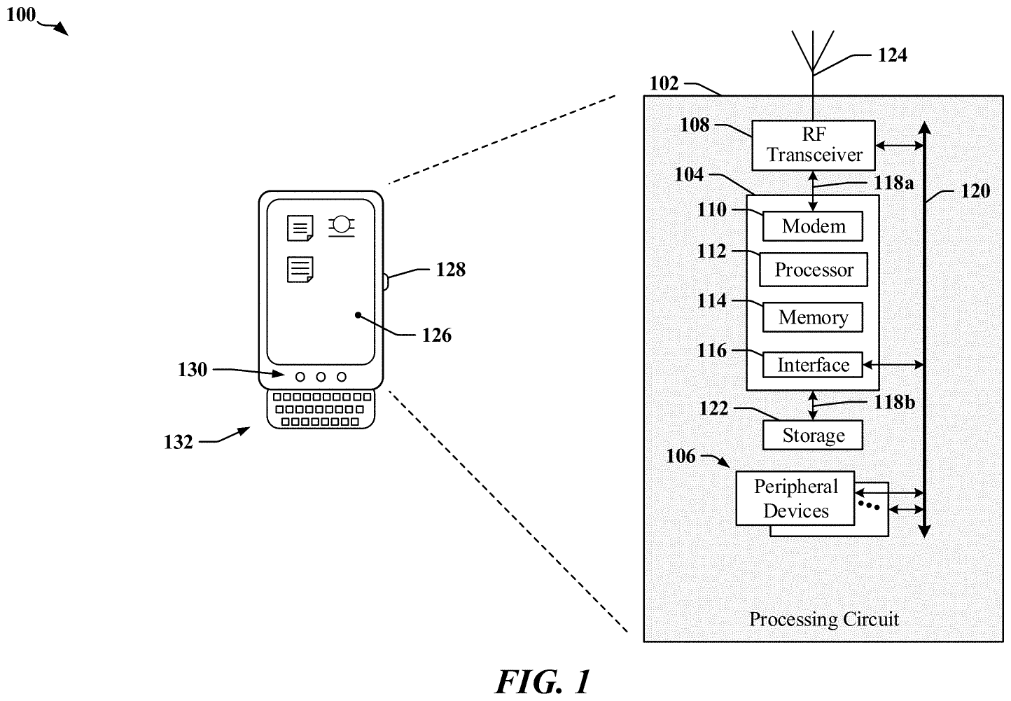

FIG. 1 illustrates an example of an apparatus 100 that may employ a data communication bus. The apparatus 100 may include an SoC a processing circuit 102 having multiple circuits or devices 104, 106 and/or 108, which may be implemented in one or more ASICs or in an SoC. In one example, the apparatus 100 may be a communication device and the processing circuit 102 may include a processing device provided in an ASIC 104, one or more peripheral devices 106, and a transceiver 108 that enables the apparatus to communicate through an antenna 124 with a radio access network, a core access network, the Internet and/or another network.

The ASIC 104 may have one or more processors 112, one or more modems 110, on-board memory 114, a bus interface circuit 116 and/or other logic circuits or functions. The processing circuit 102 may be controlled by an operating system that may provide an application programming interface (API) layer that enables the one or more processors 112 to execute software modules residing in the on-board memory 114 or other processor-readable storage 122 provided on the processing circuit 102. The software modules may include instructions and data stored in the on-board memory 114 or processor-readable storage 122. The ASIC 104 may access its on-board memory 114, the processor-readable storage 122, and/or storage external to the processing circuit 102. The on-board memory 114, the processor-readable storage 122 may include read-only memory (ROM) or random-access memory (RAM), electrically erasable programmable ROM (EEPROM), flash cards, or any memory device that can be used in processing systems and computing platforms. The processing circuit 102 may include, implement, or have access to a local database or other parameter storage that can maintain operational parameters and other information used to configure and operate the apparatus 100 and/or the processing circuit 102. The local database may be implemented using registers, a database module, flash memory, magnetic media, EEPROM, soft or hard disk, or the like. The processing circuit 102 may also be operably coupled to external devices such as the antenna 124, a display 126, operator controls, such as switches or buttons 128, 130 and/or an integrated or external keypad 132, among other components. A user interface module may be configured to operate with the display 126, external keypad 132, etc. through a dedicated communication link or through one or more serial data interconnects.

The processing circuit 102 may provide one or more buses 118a, 118b, 120 that enable certain devices 104, 106, and/or 108 to communicate. In one example, the ASIC 104 may include a bus interface circuit 116 that includes a combination of circuits, counters, timers, control logic and other configurable circuits or modules. In one example, the bus interface circuit 116 may be configured to operate in accordance with communication specifications or protocols. The processing circuit 102 may include or control a power management function that configures and manages the operation of the apparatus 100.

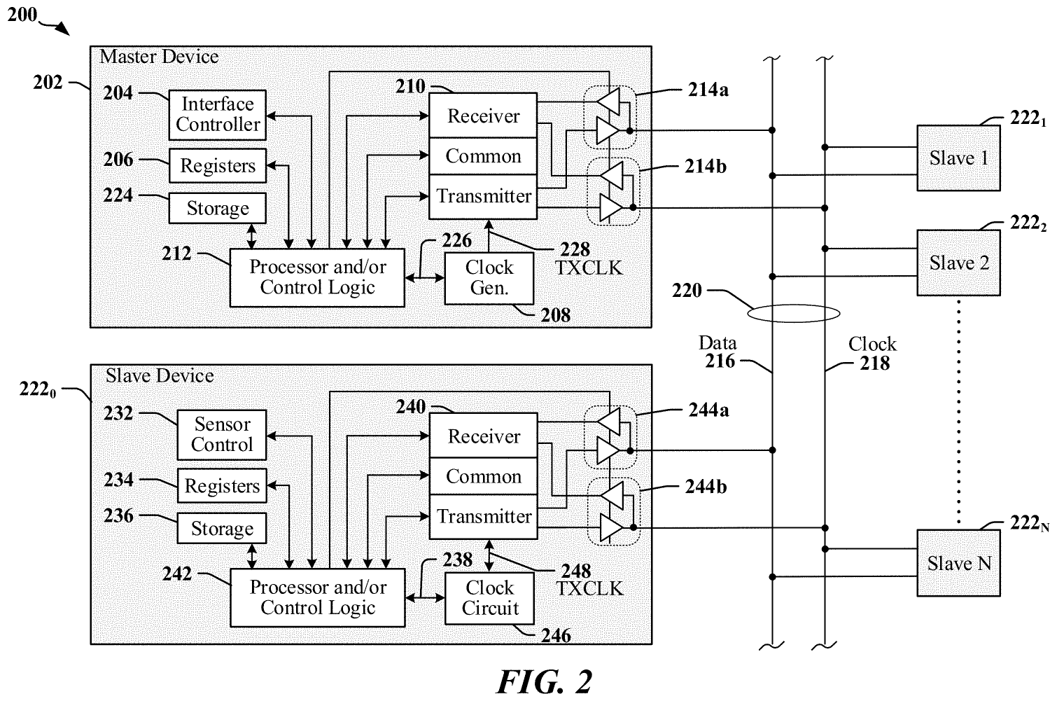

FIG. 2 illustrates a first example of an apparatus 200 employing a data link that may be used to communicatively couple two or more devices. Here, the apparatus 200 includes multiple devices 202, and 222₀-222_{N} coupled to a serial bus 220. The devices 202 and 222₀-222_{N} may be implemented in one or more semiconductor IC devices, such as an application processor, SoC or ASIC. In various implementations the devices 202 and 222₀-222_{N} may include, support or operate as a modem, a signal processing device, a display driver, a camera, a user interface, a sensor, a sensor controller, a media player, a transceiver, and/or other such components or devices. In some examples, one or more of the slave devices 222₀-222_{N} may be used to control, manage or monitor a sensor device. Communication between devices 202 and 222₀-222_{N} over the serial bus 220 is controlled by a bus master device 202. Certain types of bus can support multiple bus masters 202.

In one example, a master device 202 may include an interface controller 204 that may manage access to the serial bus, configure dynamic addresses for slave devices 222₀-222_{N} and/or generate a clock signal 228 to be transmitted on a clock line 218 of the serial bus 220. The master device 202 may include configuration registers 206 or other storage 224, and other control logic 212 configured to handle protocols and/or higher level functions. The control logic 212 may include a processing circuit such as a state machine, sequencer, signal processor or general-purpose processor. The master device 202 includes a transceiver 210 and line drivers/receivers 214a and 214b. The transceiver 210 may include receiver, transmitter and common circuits, where the common circuits may include timing, logic and storage circuits and/or devices. In one example, the transmitter encodes and transmits data based on timing in the clock signal 228 provided by a clock generation circuit 208. Other timing clocks 226 may be used by the control logic 212 and other functions, circuits or modules.

At least one device 222₀-222_{N} may be configured to operate as a slave device on the serial bus 220 and may include circuits and modules that support a display, an image sensor, and/or circuits and modules that control and communicate with one or more sensors that measure environmental conditions. In one example, a slave device 222₀ configured to operate as a slave device may provide a control function, module or circuit 232 that includes circuits and modules to support a display, an image sensor, and/or circuits and modules that control and communicate with one or more sensors that measure environmental conditions. The slave device 222₀ may include configuration registers 234 or other storage 236, control logic 242, a transceiver 240 and line drivers/receivers 244a and 244b. The control logic 242 may include a processing circuit such as a state machine, sequencer, signal processor or general-purpose processor. The transceiver 240 may include receiver, transmitter and common circuits, where the common circuits may include timing, logic and storage circuits and/or devices. In one example, the transmitter encodes and transmits data based on timing in a clock signal 248 provided by clock generation and/or recovery circuits 246. In some instances, the clock signal 248 may be derived from a signal received from the clock line 218. Other timing clocks 238 may be used by the control logic 242 and other functions, circuits or modules.

The serial bus 220 may be operated in accordance with RFFE, I2C, I3C, SPMI, or other protocols. At least one device 202, 222₀-222_{N} may be configured to operate as a master device and a slave device on the serial bus 220. Two or more devices 202, 222₀-222_{N} may be configured to operate as a master device on the serial bus 220.

In some implementations, the serial bus 220 may be operated in accordance with an I3C protocol. Devices that communicate using the I3C protocol can coexist on the same serial bus 220 with devices that communicate using I2C protocols. The I3C protocols may support different communication modes, including a single data rate (SDR) mode that is compatible with I2C protocols. High-data-rate (HDR) modes may provide a data transfer rate between 6 megabits per second (Mbps) and 16 Mbps, and some HDR modes may be provide higher data transfer rates. I2C protocols may conform to de facto I2C standards providing for data rates that may range between 100 kilobits per second (kbps) and 3.2 Mbps. I2C and I3C protocols may define electrical and timing aspects for signals transmitted on the 2-wire serial bus 220, in addition to data formats and aspects of bus control. In some aspects, the I2C and I3C protocols may define direct current (DC) characteristics affecting certain signal levels associated with the serial bus 220, and/or alternating current (AC) characteristics affecting certain timing aspects of signals transmitted on the serial bus 220. In some examples, a 2-wire serial bus 220 transmits data on a data line 216 and a clock signal on the clock line 218. In some instances, data may be encoded in the signaling state, or transitions in signaling state of the data line 216 and the clock line 218.

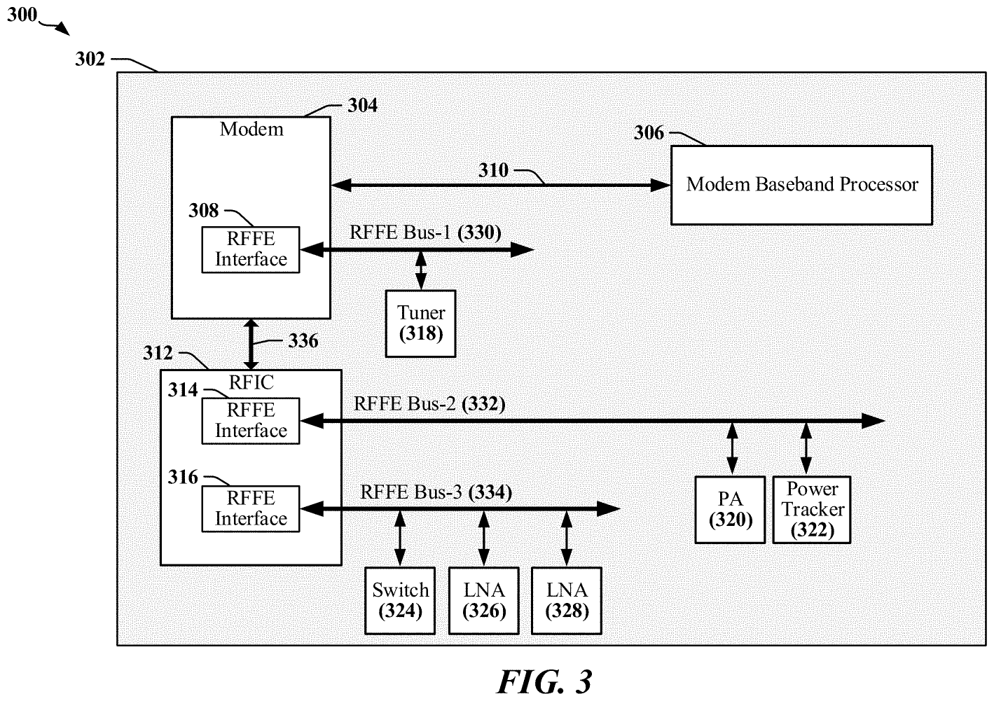

FIG. 3 illustrates a second example of an apparatus 300 employing data links that may be used to communicatively couple two or more devices. In this example, a chipset or device 302 employs multiple RFFE buses 330, 332, 334 to couple various RF front-end devices 318, 320, 322, 324, 326 328. A modem 304 includes an RFFE interface 308 that couples the modem 304 to a first RFFE bus 330. The modem 304 may communicate with a baseband processor 306 and a Radio-Frequency IC (RFIC 312) through one or more communication links 310, 336. The illustrated device 302 may be embodied in one or more of a mobile communication device, a mobile telephone, a mobile computing system, a mobile telephone, a notebook computer, a tablet computing device, a media player, a gaming device, a wearable computing and/or communication device, an appliance, or the like.

In various examples, the device 302 may be implemented with one or more baseband processors 306, modems 304, RFICs 312, multiple communication links 310, 336, multiple RFFE buses 330, 332, 334 and/or other types of buses. The device 302 may include other processors, circuits, modules and may be configured for various operations and/or different functionalities. In the example illustrated in FIG. 3, the Modem is coupled to an RF tuner 318 through its RFFE interface 308 and the first RFFE bus 330. The RFIC 312 may include one or more RFFE interfaces 314, 316, controllers, state machines and/or processors that configure and control certain aspects of the RF front-end. The RFIC 312 may communicate with a PA 320 and a power tracking module 322 through a first of its RFFE interfaces 314 and the second RFFE bus 332. The RFIC 312 may communicate with a switch 324 and one or more LNAs 326, 328.

Bus latency can affect the ability of a serial bus to handle high-priority, real-time and/or other time-constrained messages. Low-latency messages, or messages requiring low bus latency, may relate to sensor status, device-generated real-time events and virtualized GPIO state. In one example, bus latency may be measured as the time elapsed between a message becoming available for transmission and the delivery of the message or, in some instances, commencement of transmission of the message. Other measures of bus latency may be employed. Bus latency typically includes delays incurred while higher priority messages are transmitted, interrupt processing, the time required to terminate a datagram in process on the serial bus, the time to transmit commands causing bus turnaround between transmit mode and receive mode, bus arbitration and/or command transmissions specified by protocol.

In certain examples, latency-sensitive messages may include coexistence messages. Coexistence messages are transmitted in a multisystem platform to prevent or reduce instances of certain device types impinging on each other, including for example, switches 324, LNAs 326, 328, PAs 320 and other types of device that operate concurrently in a manner that can generate inter-device interference, or that could potentially cause damage to one or more devices. Devices that may interfere with one another may exchange coexistence management (CxM) messages to permit each device to signal imminent actions that may result in interference or conflict. CxM messages may be used to manage operation of shared components including a switch 324, LNA 326, 328, PA 320 and/or an antenna.

Multi-drop interfaces such as RFFE, SPMI, I3C, etc. can reduce the number of physical input/output (I/O) pins used to communicate between multiple devices. Protocols that support communication over a multi-drop serial bus define a datagram structure used to transmit command, control and data payloads. Datagram structures for different protocols define certain common features, including addressing used to select devices to receive or transmit data, clock generation and management, interrupt processing and device priorities. In this disclosure, the example of RFFE protocols may be employed to illustrate certain aspects disclosed herein. However, the concepts disclosed herein are applicable to other serial bus protocols and standards.

In accordance with certain aspects disclosed herein, a two-wire serial bus may be adapted to operate alternately in a conventional two-wire mode and in a one-wire mode. In one example, the serial bus may be operated according to RFFE protocols such that the clock and data lines are used for communication with two-wire slave devices coupled to the serial bus and the data line is used without a clock signal for communication with one-wire slave devices coupled to the serial bus. The bus master may use pulse-width modulation to encode data transmitted to one-wire slave devices.

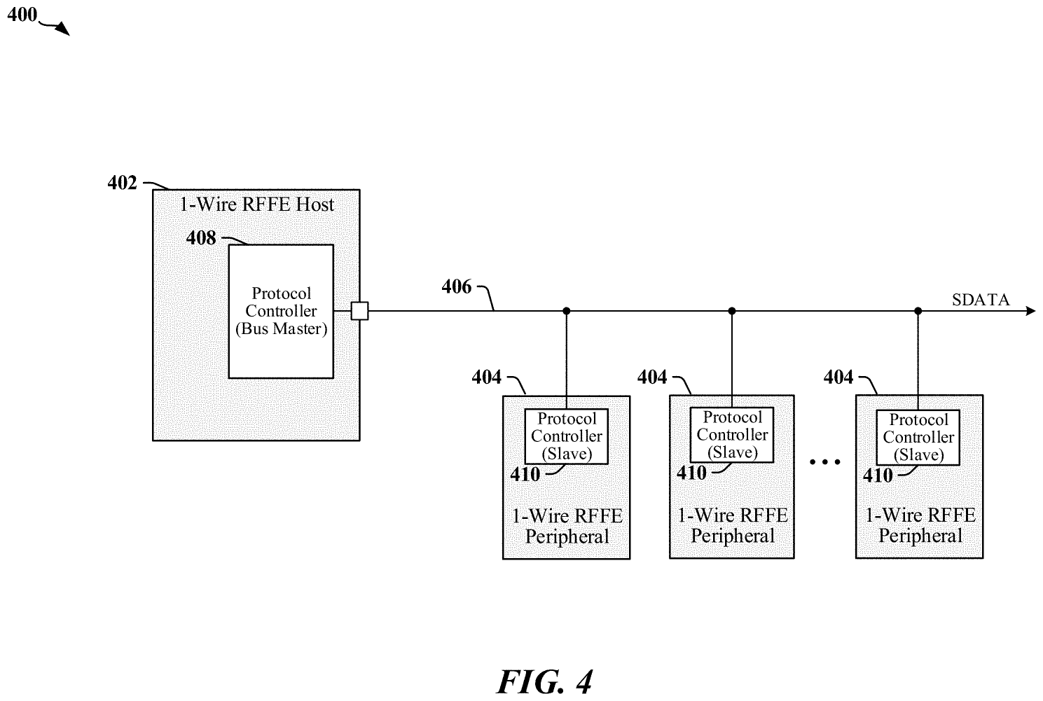

FIG. 4 illustrates a system 400 in which a bus master 402 communicates with one or more one-wire slave devices 404 in accordance with certain aspects disclosed herein. The bus master 402 may be provided in an RFIC, modem, application processor or another type of device. The bus master 402 may be adapted to exchange data with the one-wire slave devices 404 over a single wire, such as the SDATA line 406 in the illustrated system 400. Data can be encoded in a signal transmitted over the SDATA line 406, where the signal includes clock information that can be used by the receiving device to decode data from the signal. Data may be encoded using a pulse-width modulation (PWM) scheme when the system 400 is operated in accordance with certain aspects disclosed herein. The PWM scheme may produce a signal that includes a pulse during each bit period defined by a clock signal that controls transmissions over the SDATA line 406. A pulse is generated regardless of the value of the data transmitted in the bit period.

In one example, a bit having a value of ‘1’ may be represented as a pulse having a first duration and a bit having a value of ‘0’ may be represented as a pulse having a second duration. The first duration may be greater than the second duration, or the second duration may be greater than the first duration.

In the illustrated example, the bus master 402 and the one-wire slave devices 404 may be operated in general accordance with RFFE protocols, which in some implementations may be modified to support a 1-Wire mode of communication. Modifications may include the inclusion of a PWM encoder/decoder. In other examples, communication over the SDATA line 406 may be conducted in accordance with another protocol, such as an I3C and/or SPMI protocol which has been modified to support the 1-Wire mode of communication.

The bus master 402 and the one-wire slave devices 404 typically include respective protocol controllers 408, 410. The protocol controllers 408, 410 may have a processor, controller, state machine or other logic configured to support one or more protocols. The protocol controller 408 in the bus master 402 may be further configured to manage communication over the SDATA line 406. In some instances, the protocol controller 408 performs some of the functions of the bus master. In some implementations, the protocol controller 408 in the bus master 402 may be used to configure one or more one-wire slave devices 404. The bus master 402 may determine a configuration of a one-wire slave device 404 that is a designated recipient of data to be transmitted over the SDATA line 406, and may cause the protocol controller 408 to encode data intended for the recipient one-wire slave device 404 in a signal to be transmitted over the SDATA line 406 and addressed to the one-wire slave device 404.

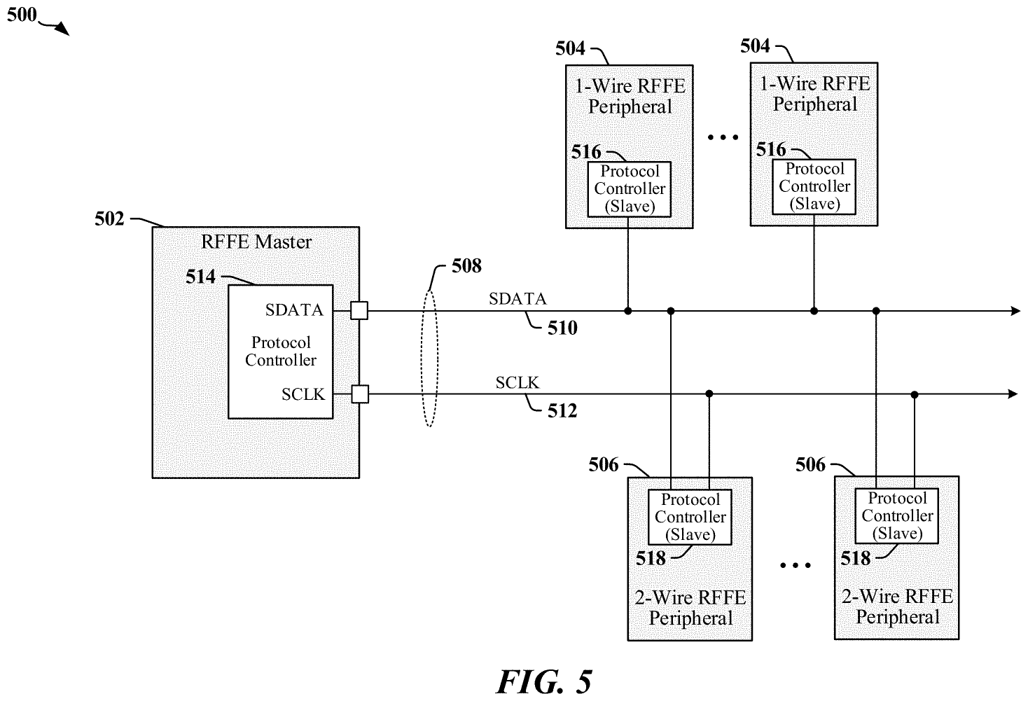

FIG. 5 illustrates a system 500 in which one-wire slave devices 504 and two-wire slave devices 506 can coexist on a serial bus 508, and where a bus master 502 can communicate with both the one-wire slave devices 504 and the two-wire slave devices 506 in accordance with certain aspects disclosed herein. The bus master 502 may be provided in an RFIC, modem, application processor or another type of device. The bus master 502 is coupled to one or more slave devices 504, 506 through at least the SDATA line 510 of a two-wire serial bus 508 that also has an SCLK line 512. Data can be encoded in a data signal transmitted over the SDATA line 510. In a 1-Wire mode of communication, a receiver can extract the data using a clock information embedded in a PWM signal transmitted over the SDATA line 510. In a 2-Wire mode of communication, a receiver can extract the data using a clock signal transmitted over the SCLK line 512.

In the illustrated example, the serial bus 508 may be operated in general accordance with an RFFE protocol. The RFFE protocols may be modified to support a 1-Wire mode of communication in addition to conventional 2-Wire modes of communication. Modifications may include the inclusion of a PWM encoder/decoder. In other examples, the serial bus 508 may be operated in general accordance with another protocol, such as an I3C, SPMI, or another protocol. In the system 500, each one-wire slave device 504 and each two-wire slave device 506 is coupled to the SDATA line 510. The one-wire slave devices 504 are configured for a 1-Wire mode of communication, while the two-wire slave devices 506 are also coupled to the SCLK line 512 to receive the clock signal used in the 2-Wire mode of communication.

The bus master 502 and the slave devices 504, 506 may include or be implemented by respective protocol controllers 514, 516, 518. The protocol controllers 514, 516, 518 may have a processor, controller, state machine or other logic configured to support one or more protocols. The protocol controller 514 in the bus master 502 may be further configured to manage communication over the serial bus 508.

In some implementations, the protocol controller 514 in the bus master 502 may configure one or more slave devices 504, 506. The protocol controller 514 may determine a configuration of a slave device 504, 506 that is a designated recipient of data to be transmitted over the serial bus 508, and may encode data in a signal to be transmitted over the SDATA line 510 accordingly. In some instances, a broadcast message directed to a combination of one-wire slave devices 504 and two-wire slave devices 506 may be sent twice, once in the 1-wire mode of communication and once in the 2-wire mode of communication. The protocol controller 514 may additionally determine whether a clock signal is to be transmitted over the SCLK line 512 during a transaction. In some implementations, the clock signal is suppressed in a transaction initiated for the exchange of data when the serial bus 508 is operated in a 1-Wire mode of communication.

Conventional bus protocols may be adapted to support 1-Wire modes of communication for the transfer of data to and from one-wire slave devices 404, 504. For example, the one-wire slave devices 404, 504 may receive and transmit data in PWM-encoded signals transmitted over the SDATA line 406, 510. The bus master 402, 502 is responsible for controlling timing of transmissions over a serial bus, and typically provides a clock signal when the bus has two or more wires. When one-wire slave devices 404, 504 transmit to a bus master 402, 502 PWM encoders in the one-wire slave devices 404, 504 convert data bits to pulse durations consistent with timing maintained by the bus master 402, 502 even when a clock signal provided by the bus master 402, 502 is not available.

Conventional protocols provide no clearly defined technique for supporting slave read operations by the bus master 402, 502 when the slave does not have access to a clock signal provided by the bus master 402, 502. The bus master 402, 502 may use such a clock signal for originating the PWM sequence and for maintaining timing used to generated PWM signaling in systems 400, 500 that support 1-Wire modes of communication.

In some implementations, a protocol controller 408, 514 may be configured to provide timing information in a system start condition or other signaling transmitted at the beginning of a transaction conducted in 1-Wire modes of communication. The timing information may define the duration of bit intervals and/or the center points of bit intervals to enable a receiver to distinguish between pulse widths used to encode data in a PWM signal. A one-wire slave device 404, 504 may initiate a PWM decoder during slave write operations based on the timing information, and the decoder may operate reliably using timing information in the PWM-encoded signal transmitted by the bus master 402, 502. When responding to a slave read command, the one-wire slave device 404, 504 may use the timing information to calibrate and/or synchronize an internal clock signal at the one-wire slave device 404, 504. In some instances, however, the one-wire slave device 404, 504 may not generate an internal clock signal and may not have another timing reference usable for PWM encoding.

Certain aspects disclosed herein relate to the provision of timing references at one-wire slave devices 404, 504 that do not have a local free-running clock source. Timing references may be provided by the bus master 402, 502 during a bus read to enable a PWM encoder at a one-wire slave device 404, 504 to maintain bus synchronization in the absence of a local free-running clock source. In some implementations, the bus master 402, 502 may indicate an intent to provide timing references in information sent in a header section of the datagram that includes the slave read command. The header section is transmitted by the bus master 402, 502 and precedes a payload section that is conventionally transmitted by a slave during a slave read, and precedes a payload section transmitted by the bus master 402, 502 during a slave write. A bus master 402, 502 may operate as a transmitter during a portion of each bit interval of the payload when a slave read is performed in a 1-Wire mode of communication conducted according to certain aspects disclosed herein. The bus master 402, 502 may, for example, drive one or more transitions in PWM pulses during each bit transmission interval. The resultant master-originated PWM slave read transaction can support one-wire slave devices 404, 504 that do not have a local free-running clock source.

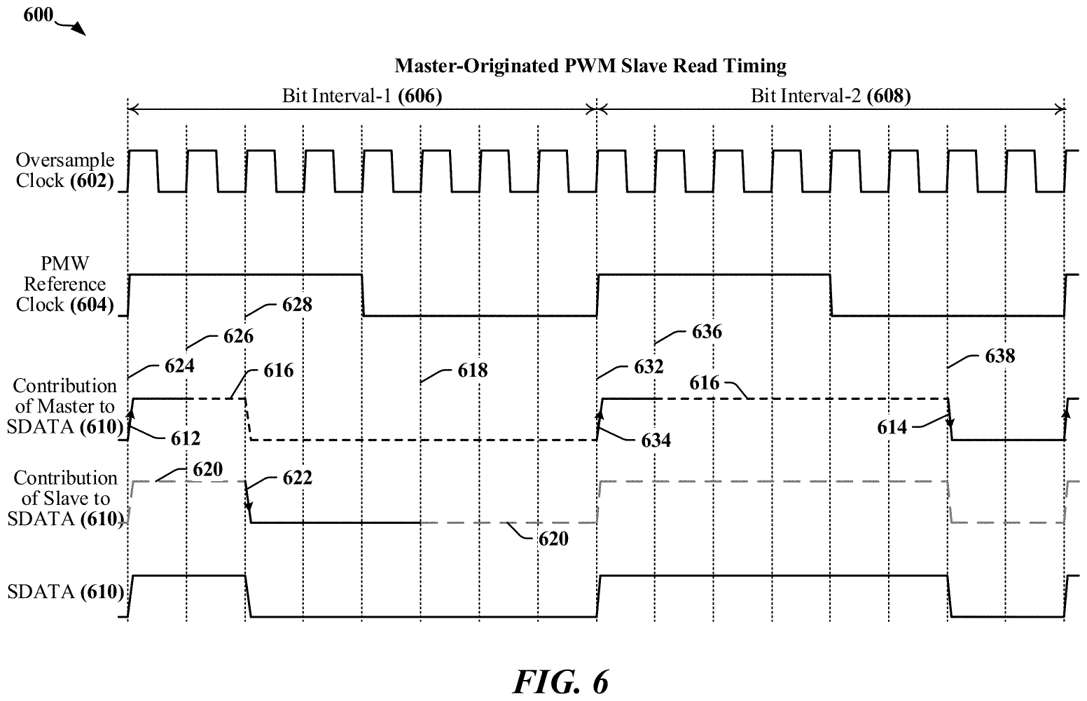

FIG. 6 illustrates certain aspects of timing 600 related to a master-originated PWM slave read transaction provided in accordance with certain aspects disclosed herein. A bus master 402, 502 may correspond to the bus master device 202 of FIG. 2, which has a transceiver 210 and a line driver/receiver 214a coupled to a data line 216. A one-wire slave device 404, 504 may include certain features of the slave device 2220 of FIG. 2, which has a transceiver 210 and a line driver/receiver 244a coupled to the data line 216. Line drivers in the bus master 402, 502 and one-wire slave devices 404, 504 may present a high impedance to the data line 216 when disabled and/or when receiving data during a slave write transaction.

The bus master 402, 502 may generate an internal oversampling clock signal 602 that is used to control timing of PWM encoders and decoders. A bit-reference clock signal 604 may be generated by dividing the oversampling clock signal 602 to obtain a clock period that defines a bit interval 606, 608 used to communicate one PWM-encoded bit. When data is read from a one-wire slave device 404, 504, the bus master 402, 502 drives an initiating transition 612, 634 at the beginning of each bit interval 606, 608 to initiate a pulse on the SDATA line 610. The one-wire slave device 404, 504 may be adapted to drive a terminating transition 622 on the SDATA line 610 to terminate the pulse when a short duration pulse is required. The bus master 402, 502 drives a terminating transition 614 later in the bit interval when the one-wire slave device 404, 504 does not provide the earlier terminating transition 622.

In the illustrated example, an initiating transition 612 is provided at the beginning 624 of a first cycle of the oversampling clock signal 602 in the first bit interval 606, and the initiating transition 612 causes the SDATA line 610 to transition from a low voltage state to a high voltage state. In other examples, an active-low pulse may be provided. The bus master 402, 502 releases the SDATA line 610 at the end 626 of the first cycle of the oversampling clock signal 602. The bus master 402, 502 may release the SDATA line 610 by causing its line driver to enter a high impedance state 616. In one example, the bus master 402, 502 may cause a pull-up resistor to be coupled to the SDATA line 610 that causes the SDATA line 610 to remain at the high voltage state. In another example, a keeper circuit coupled to the SDATA line 610 causes the SDATA line 610 to remain at the high voltage state. The line driver of the one-wire slave device 404, 504 is in a high-impedance state 620 at the commencement of the first bit interval 606.

In the illustrated example, a PWM encoder in the one-wire slave device 404, 504 determines that a short pulse is to be provided in the first bit interval 606, and the one-wire slave device 404, 504 provides a terminating transition 622 at the end 628 of the second cycle of the oversampling clock signal 602 in the first bit interval 606. The terminating transition 622 causes the SDATA line 610 to transition from the high voltage state to the low voltage state. In some implementations, the bus master 402, 502 detects the terminating transition 622 and/or detects that the SDATA line 610 is in the low voltage state and may cause a pull-down resistor to be coupled to the SDATA line 610 that causes the SDATA line 610 after disconnecting the pull-up resistor. The one-wire slave device 404, 504 may release the SDATA line 610 at some point in time by causing its line driver to reenter the high-impedance state 620, here at the end 618 of the fifth cycle of the oversampling clock signal 602 in the first bit interval 606. The SDATA line 610 is held at the low voltage state by the pull-down resistor and/or the operation of the keeper circuit.

At the commencement of the second bit interval 608, an initiating transition 634 is provided by the bus master 402, 502. The initiating transition 634 is provided at the beginning 632 of a first cycle of the oversampling clock signal 602 in the second bit interval 608, and the initiating transition 634 causes the SDATA line 610 to transition from the low voltage state to the high voltage state. The bus master 402, 502 releases the SDATA line 610 at the end 636 of the first cycle of the oversampling clock signal 602. The bus master 402, 502 may release the SDATA line 610 by causing its line driver to enter a high impedance state 616. In one example, the bus master 402, 502 may cause a pull-up resistor to be coupled to the SDATA line 610 that causes the SDATA line 610 to remain at the high voltage state, while disconnecting a pull-down resistor from the SDATA line 610 in some instances. In another example, a keeper circuit coupled to the SDATA line 610, and the keeper circuit that causes the SDATA line 610 to remain at the high voltage state. The line driver of the one-wire slave device 404, 504 is in a high-impedance state 620 at the commencement of the second bit interval 608.

In the illustrated example, the PWM encoder in the one-wire slave device 404, 504 determines that a long pulse is to be provided in the first bit interval 606, and the one-wire slave device 404, 504 does not act during the second bit interval 608. The line driver of the one-wire slave device 404, 504 in the high-impedance state 620. At some point, the bus master 402, 502 determines that a long pulse has been provided and/or that the SDATA line 610 has remained in the high voltage state for a sufficient period of time to indicate a long pulse. The bus master 402, 502 activates its line driver and provides a terminating transition 614 at the end 638 of the sixth cycle of the oversampling clock signal 602 in the second bit interval 608. The terminating transition 622 causes the SDATA line 610 to transition from the high voltage state to the low voltage state.

The timing 600 described in relation to FIG. 6 is provided as one illustrative example of various possible PWM encoding schemes, timing intervals, and device operation. The timing 600 of transitions, detection of transitions and other timing aspects described in relation to FIG. 6 may be determined by configuration, frequency of the oversampling clock signal 602 and/or application requirements for any given implementation. The timing 600 illustrated in FIG. 6 provides timing references and enables and/or supports line drive behavior in bus masters 402, 502 and one-wire slave devices 404, 504 that maintain accurate bit-level timing while avoiding high cross-bar currents.

The provision of initiating transitions 612, 634 at the beginning of each bit interval 606, 608 provides a clock reference to the one-wire slave devices 404, 504 that marks the beginning of bit intervals 606, 608. In one example, each bit interval 606, 608 provides a time slot within which one-wire slave devices 404, 504 can drive a terminating transition 622 to send a data bit with a value of ‘0’, and where the one-wire slave devices 404, 504 can send a data bit with a value of ‘1’ by refraining from driving a terminating transition.

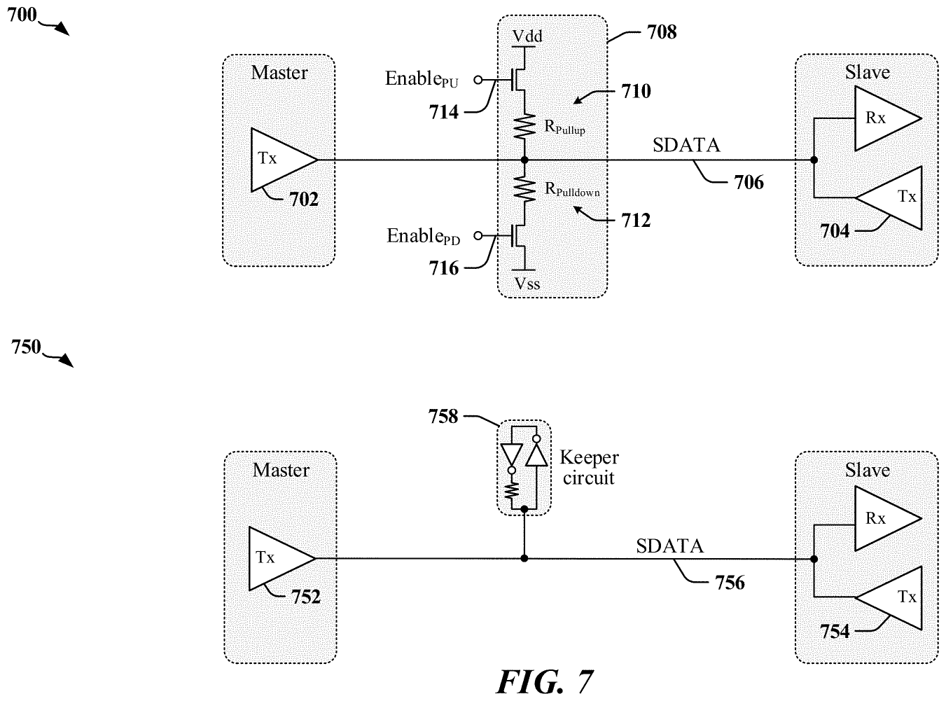

FIG. 7 illustrates an example of a line termination circuit 700 and an example of a keeper circuit 750 that may be used to facilitate transmission of a master-originated PWM slave read transaction. In some implementations, a bus master 402, 502 and one-wire slave devices 404, 504 include line drivers 702, 704 that can be used to transmit over an SDATA line 706. The line drivers 702, 704 may present a high-impedance to the SDATA line 706 when inactivated or disabled. The line driver 702 in the bus master 402, 502 may include or be coupled to a termination circuit 708. A pull-up resistor 710 may be coupled to the SDATA line 706 through a switch controlled by a pull-up enable signal 714. A pull-down resistor 712 may be coupled to the SDATA line 706 through a switch controlled by a pull-down enable signal 716. In some instances, the enable signals 714, 716 are provided by a protocol controller 408, 514 during 1-Wire communication.

In some implementations, a bus master 402, 502 and one-wire slave devices 404, 504 include line drivers 752, 754 that can be used to transmit over an SDATA line 756. The line drivers 752, 754 may present a high-impedance to the SDATA line 756 when inactivated or disabled. The line driver 752 in the bus master 402, 502 may include or be coupled to a keeper circuit 758. The keeper circuit 758 may be configured as a positive feedback circuit that drives the SDATA line 756 through a high impedance output, and receives feedback from the SDATA line 756 through a low impedance input. The keeper circuit 758 may be configured to maintain the last asserted voltage on the SDATA line 756. The keeper circuit 758 can be easily overcome by line drivers in the bus master 402, 502 and one-wire slave devices 404, 504.

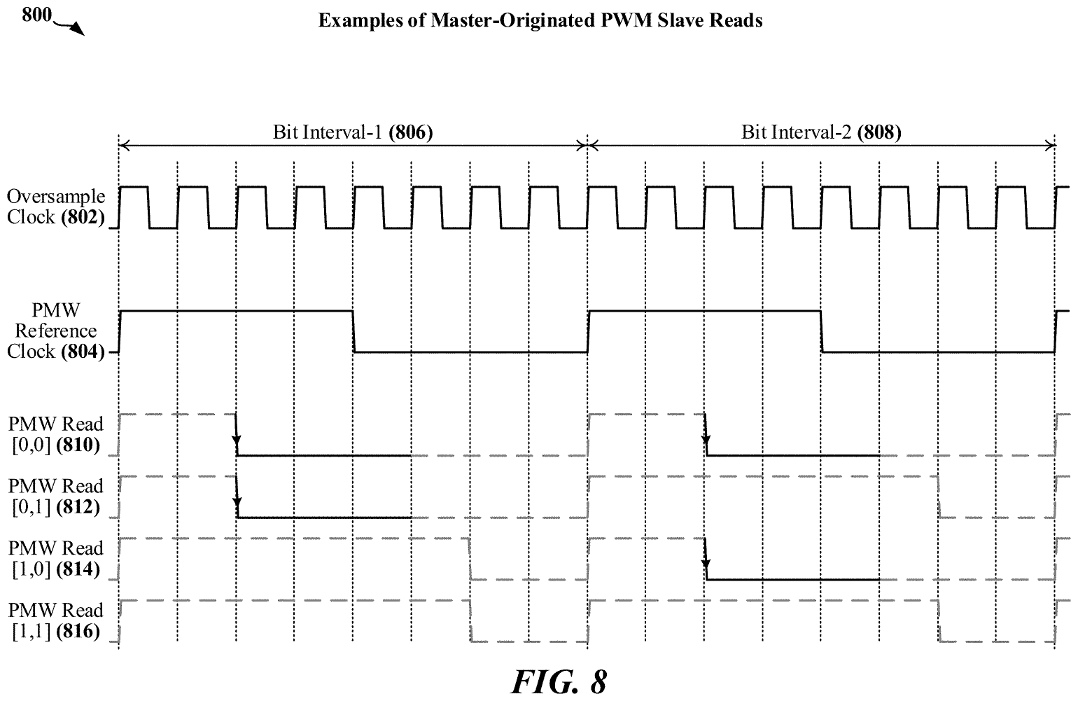

FIG. 8 illustrates timing 800 related to transmissions during master-originated PWM slave read transactions provided in accordance with certain aspects disclosed herein. A bus master 402, 502 may generate an internal oversampling clock signal 802 that is used to control timing of PWM encoders and decoders. A bit-reference clock signal 804 may be generated by dividing the oversampling clock signal 802 to obtain a clock period that defines a bit interval 806, 808 used to communicate one PWM-encoded bit.

Four examples of transmissions 810, 812, 814, 816 are illustrated. In the first transmission 810, a pair of bits [0, 0] is transmitted by providing a short pulse in two bit intervals 806, 808. In the second transmission 812, a pair of bits [0, 1] is transmitted by providing a short pulse in a first bit interval 806, and a long pulse in a second bit interval 808. In the third transmission 814, a pair of bits [1, 0] is transmitted by providing a long pulse in the first bit interval 806, and a short pulse in the second bit interval 808. In the fourth transmission 816, a pair of bits [1, 1] is transmitted by providing a long pulse in both bit intervals 806, 808.

### Examples of Processing Circuits and Methods

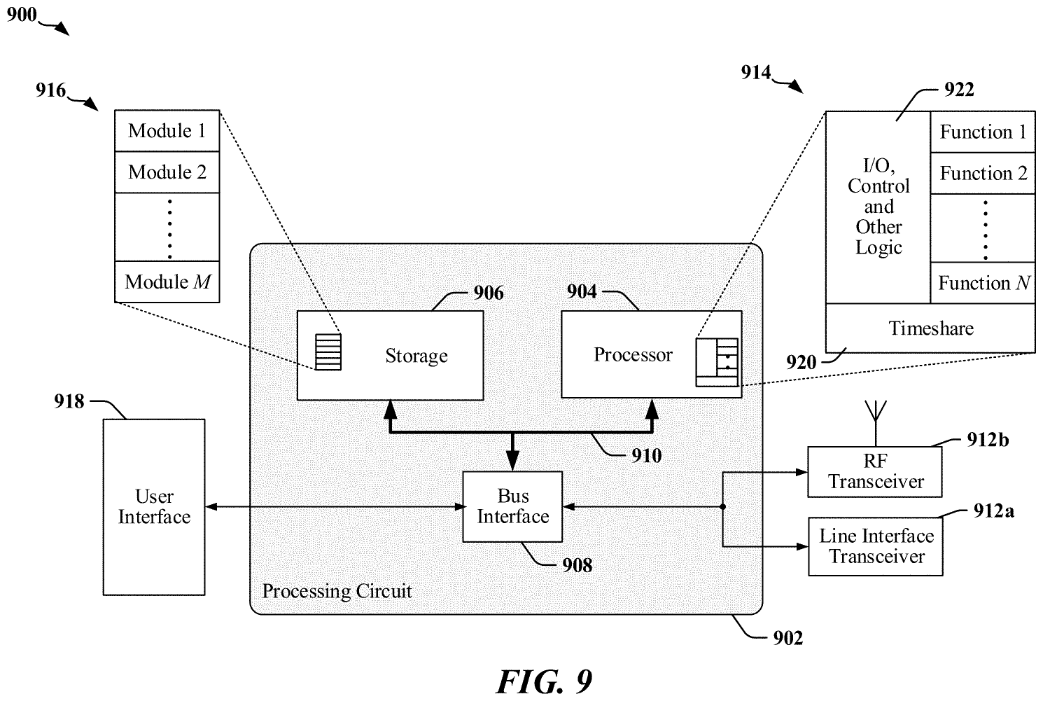

FIG. 9 is a diagram illustrating an example of a hardware implementation for an apparatus 900. In some examples, the apparatus 900 may perform one or more functions disclosed herein. In accordance with various aspects of the disclosure, an element, or any portion of an element, or any combination of elements as disclosed herein may be implemented using a processing circuit 902. The processing circuit 902 may include one or more processors 904 that are controlled by some combination of hardware and software modules. Examples of processors 904 include microprocessors, microcontrollers, digital signal processors (DSPs), SoCs, ASICs, field programmable gate arrays (FPGAs), programmable logic devices (PLDs), state machines, sequencers, gated logic, discrete hardware circuits, and other suitable hardware configured to perform the various functionality described throughout this disclosure. The one or more processors 904 may include specialized processors that perform specific functions, and that may be configured, augmented or controlled by one of the software modules 916. The one or more processors 904 may be configured through a combination of software modules 916 loaded during initialization, and further configured by loading or unloading one or more software modules 916 during operation.

In the illustrated example, the processing circuit 902 may be implemented with a bus architecture, represented generally by the bus 910. The bus 910 may include any number of interconnecting buses and bridges depending on the specific application of the processing circuit 902 and the overall design constraints. The bus 910 links together various circuits including the one or more processors 904, and storage 906. Storage 906 may include memory devices and mass storage devices, and may be referred to herein as computer-readable media and/or processor-readable media. The bus 910 may also link various other circuits such as timing sources, timers, peripherals, voltage regulators, and power management circuits. A bus interface 908 may provide an interface between the bus 910 and one or more transceivers 912a, 912b. A transceiver 912a, 912b may be provided for each networking technology supported by the processing circuit. In some instances, multiple networking technologies may share some or all of the circuitry or processing modules found in a transceiver 912a, 912b. Each transceiver 912a, 912b provides a means for communicating with various other apparatus over a transmission medium. In one example, a transceiver 912a may be used to couple the apparatus 900 to a multi-wire bus. In another example, a transceiver 912b may be used to connect the apparatus 900 to a radio access network. Depending upon the nature of the apparatus 900, a user interface 918 (e.g., keypad, display, speaker, microphone, joystick) may also be provided, and may be communicatively coupled to the bus 910 directly or through the bus interface 908.

A processor 904 may be responsible for managing the bus 910 and for general processing that may include the execution of software stored in a computer-readable medium that may include the storage 906. In this respect, the processing circuit 902, including the processor 904, may be used to implement any of the methods, functions and techniques disclosed herein. The storage 906 may be used for storing data that is manipulated by the processor 904 when executing software, and the software may be configured to implement any one of the methods disclosed herein.

One or more processors 904 in the processing circuit 902 may execute software. Software shall be construed broadly to mean instructions, instruction sets, code, code segments, program code, programs, subprograms, software modules, applications, software applications, software packages, routines, subroutines, objects, executables, threads of execution, procedures, functions, algorithms, etc., whether referred to as software, firmware, middleware, microcode, hardware description language, or otherwise. The software may reside in computer-readable form in the storage 906 or in an external computer-readable medium. The external computer-readable medium and/or storage 906 may include a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a “flash drive,” a card, a stick, or a key drive), RAM, ROM, a programmable read-only memory (PROM), an erasable PROM (EPROM) including EEPROM, a register, a removable disk, and any other suitable medium for storing software and/or instructions that may be accessed and read by a computer. The computer-readable medium and/or storage 906 may also include, by way of example, a carrier wave, a transmission line, and any other suitable medium for transmitting software and/or instructions that may be accessed and read by a computer. Computer-readable medium and/or the storage 906 may reside in the processing circuit 902, in the processor 904, external to the processing circuit 902, or be distributed across multiple entities including the processing circuit 902. The computer-readable medium and/or storage 906 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

The storage 906 may maintain software maintained and/or organized in loadable code segments, modules, applications, programs, etc., which may be referred to herein as software modules 916. Each of the software modules 916 may include instructions and data that, when installed or loaded on the processing circuit 902 and executed by the one or more processors 904, contribute to a run-time image 914 that controls the operation of the one or more processors 904. When executed, certain instructions may cause the processing circuit 902 to perform functions in accordance with certain methods, algorithms and processes described herein.

Some of the software modules 916 may be loaded during initialization of the processing circuit 902, and these software modules 916 may configure the processing circuit 902 to enable performance of the various functions disclosed herein. For example, some software modules 916 may configure internal devices and/or logic circuits 922 of the processor 904, and may manage access to external devices such as a transceiver 912a, 912b, the bus interface 908, the user interface 918, timers, mathematical coprocessors, and so on. The software modules 916 may include a control program and/or an operating system that interacts with interrupt handlers and device drivers, and that controls access to various resources provided by the processing circuit 902. The resources may include memory, processing time, access to a transceiver 912a, 912b, the user interface 918, and so on.

One or more processors 904 of the processing circuit 902 may be multifunctional, whereby some of the software modules 916 are loaded and configured to perform different functions or different instances of the same function. The one or more processors 904 may additionally be adapted to manage background tasks initiated in response to inputs from the user interface 918, the transceiver 912a, 912b, and device drivers, for example. To support the performance of multiple functions, the one or more processors 904 may be configured to provide a multitasking environment, whereby each of a plurality of functions is implemented as a set of tasks serviced by the one or more processors 904 as needed or desired. In one example, the multitasking environment may be implemented using a timesharing program 920 that passes control of a processor 904 between different tasks, whereby each task returns control of the one or more processors 904 to the timesharing program 920 upon completion of any outstanding operations and/or in response to an input such as an interrupt. When a task has control of the one or more processors 904, the processing circuit is effectively specialized for the purposes addressed by the function associated with the controlling task. The timesharing program 920 may include an operating system, a main loop that transfers control on a round-robin basis, a function that allocates control of the one or more processors 904 in accordance with a prioritization of the functions, and/or an interrupt driven main loop that responds to external events by providing control of the one or more processors 904 to a handling function.

The processing circuit 902 may be configured to perform one or more of the functions disclosed herein. For example, the processing circuit 902 may be configured to operate as a master device coupled to a serial bus. The processing circuit 902 may be configured to initiate a pulse on a wire coupling the processing circuit 902 to a slave device, present a high impedance to the wire after initiating the pulse and determine whether a slave device has terminated the pulse early, indicating a first encoded value. When the slave device has not terminated the pulse, processing circuit 902 may be configured to terminate the pulse after a duration of time sufficient to indicate a second encoded value. In one example, the first encoded value is assigned binary 1 and the second encoded value is assigned binary 0. In another example, the first encoded value is assigned binary 0 and the second encoded value is assigned binary 1. The processing circuit 902 may be configured to determine the encoded value or may employ a separate PWM decoder.

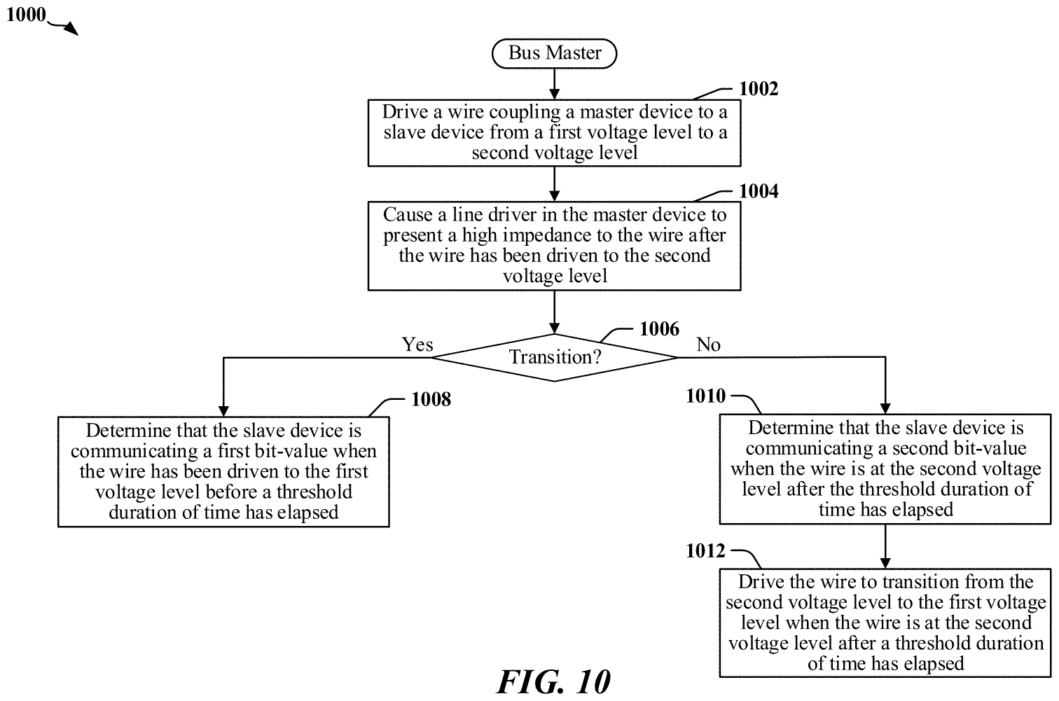

FIG. 10 is a flowchart 1000 of a method that may be performed by a master device coupled to a serial bus. One or more one-wire slave devices may be coupled to the serial bus. The master device may exchange PWM-encoded data with the one-wire slave devices. At block 1002, the master device may drive a wire coupling a master device to a slave device from a first voltage level to a second voltage level. In the example of a serial bus operated in accordance with RFFE protocols, the first voltage level may be a low voltage level such as a zero-volt level, and the second voltage level may be a high voltage level. At block 1004, the master device may cause a line driver in the master device to present a high impedance to the wire after the wire has been driven to the second voltage level. In one example, the output of the line driver may be disabled. A slave device may safely drive the wire when the line driver is presenting a high impedance to the wire.

At block 1006, the master device may wait for the wire to transition from the second voltage level to a first voltage level. The master device may wait for a threshold period of time that allows for a slave device to drive the wire to the first level, thereby causing a short-duration pulse on the wire. The period of time may correspond to the duration of a long-duration pulse. The short-duration pulse and the long-duration pulse may encode different binary values. If the master device determines that a transition has occurred, then the method continues at block 1008. Otherwise, the master device proceeds to block 1012.

At block 1008, the master device may determine that the slave device is communicating a first bit-value when the wire has been driven to the first voltage level before a threshold duration of time has elapsed.

At block 1010, the master device may determine that the slave device is communicating a second bit-value when the wire is at the second voltage level after the threshold duration of time has elapsed. At block 1012, the master device may drive the wire from the second voltage level to the first voltage level when the wire is at the second voltage level after a threshold duration of time has elapsed. The master device may cause a longer-duration pulse when it drives the wire from the second voltage level to the first voltage level after the threshold duration of time has elapsed.

In one example, the wire is driven by the master device to the second voltage level at the beginning of a bit transmission interval. In certain examples, the master device may couple a first resistor to the wire prior to causing the line driver in the master device to present the high impedance to the wire. The first resistor may be configured to pull the wire to the second voltage level. In some examples, a keeper circuit coupled to the wire is operable to hold the wire at the second voltage level after causing the line driver in the master device to present the high impedance to the wire.

In certain examples, the master device may detect that the wire has been driven to the first voltage level before the threshold duration of time has elapsed. The master device may couple a second resistor to the wire after detecting that the wire has been driven to the first voltage level before the threshold duration of time has elapsed. The second resistor may be configured to pull the wire to the first voltage level. In some examples, a keeper circuit coupled to the wire is operable to hold the wire at the first voltage level after causing the line driver in the master device to present the high impedance to the wire.

In various examples, the master device and the slave device are configured to use the wire to exchange data provided in accordance with an RFFE protocol. Certain aspects of the RFFE protocol may be adapted to support 1-Wire communication. In some instances, data is exchanged in a pulse-width modulated signal transmitted over the wire.

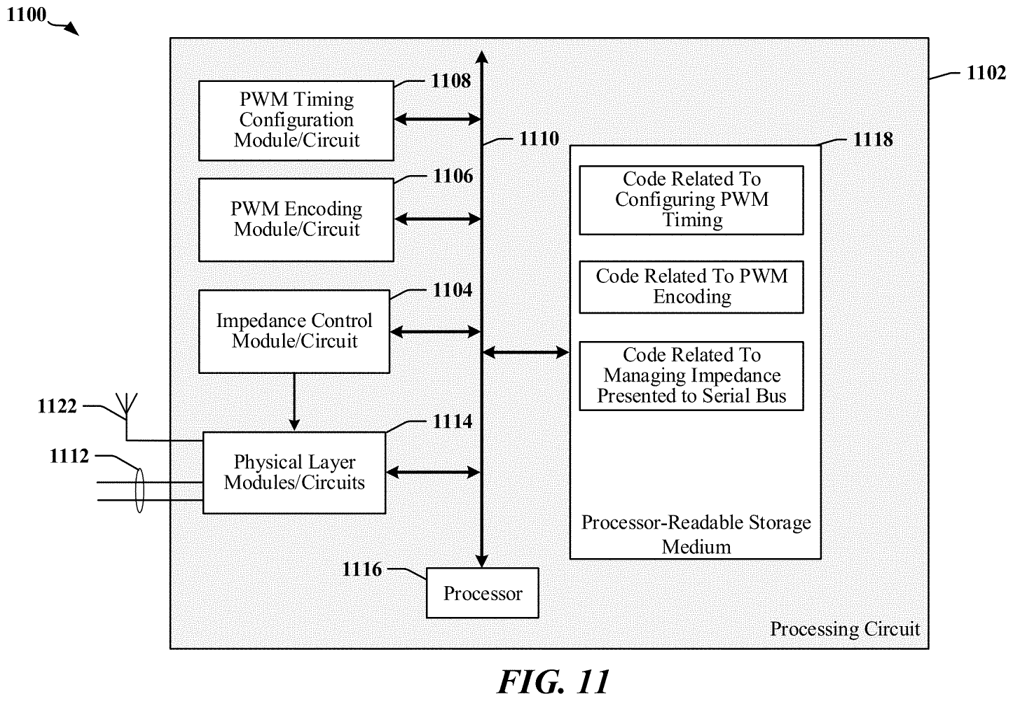

FIG. 11 is a diagram illustrating a simplified example of a hardware implementation for an apparatus 1100 employing a processing circuit 1102. The processing circuit typically has a controller or processor 1116 that may include one or more microprocessors, microcontrollers, digital signal processors, sequencers and/or state machines. The processing circuit 1102 may be implemented with a bus architecture, represented generally by the bus 1110. The bus 1110 may include any number of interconnecting buses and bridges depending on the specific application of the processing circuit 1102 and the overall design constraints. The bus 1110 links together various circuits including one or more processors and/or hardware modules, represented by the controller or processor 1116, the modules or circuits 1104, 1106 and 1108 and the processor-readable storage medium 1118. One or more physical layer circuits and/or modules 1114 may be provided to support communication over a communication link implemented using a multi-wire bus 1112, through an antenna or antenna array 1122 (to a radio access network for example), and so on. The bus 1110 may also link various other circuits such as timing sources, peripherals, voltage regulators, and power management circuits, which are well known in the art, and therefore, will not be described any further.

The processor 1116 is responsible for general processing, including the execution of software, code and/or instructions stored on the processor-readable storage medium 1118. The processor-readable storage medium 1118 may include a non-transitory storage medium. The software, when executed by the processor 1116, causes the processing circuit 1102 to perform the various functions described herein, and for any particular apparatus. The processor-readable storage medium 1118 may be used for storing data that is manipulated by the processor 1116 when executing software. The processing circuit 1102 further includes at least one of the modules 1104, 1106 and 1108. The modules 1104, 1106 and 1108 may be software modules running in the processor 1116, resident/stored in the processor-readable storage medium 1118, one or more hardware modules coupled to the processor 1116, or some combination thereof. The modules 1104, 1106 and 1108 may include microcontroller instructions, state machine configuration parameters, or some combination thereof.

In one configuration, the apparatus 1100 includes modules and/or circuits 1104 adapted to control impedance of a line driver coupled to a 1-Wire serial bus, including circuits that enable and disable the output of the line driver. The apparatus 1100 may include modules and/or circuits 1106 adapted to encode data in PWM datagrams, and modules and/or circuits 1108 adapted to manage timing associated with 1-Wire PWM transactions.

In one example, the apparatus 1100 includes physical layer circuits and/or modules 1114 that implement an interface circuit with at least one line driver adapted or configured to couple the apparatus 1100 to a 1-Wire serial bus. The apparatus 1100 may have a protocol controller configured to cause the line driver to drive the wire from a first voltage level to a second voltage level at the beginning of a bit transmission interval, cause the line driver to present a high impedance to the wire after the wire has been driven to the second voltage level, determine that a slave device is communicating a first bit-value when the wire has been driven to the first voltage level before a threshold duration of time has elapsed, determine that the slave device is communicating a second bit-value when the wire is at the second voltage level after the threshold duration of time has elapsed, and cause the line driver to drive the wire to transition from the second voltage level to the first voltage level when the wire is at the second voltage level after a threshold duration of time has elapsed.

In some implementations, the apparatus 1100 also has a first resistor tied to the second voltage level. The protocol controller may be further configured to couple the first resistor to the wire prior to causing the line driver to present the high impedance to the wire. In another example, the apparatus 1100 may have a keeper circuit coupled to the wire. The keeper circuit may be operable to hold the wire at the second voltage level when the line driver presents the high impedance to the wire.

In some implementations, the apparatus 1100 has a second resistor tied to the first voltage level. The protocol controller may be further configured to detect that the wire has been driven to the first voltage level before the threshold duration of time has elapsed, and couple the second resistor to the wire prior to causing the line driver to present the high impedance to the wire. In some examples, apparatus 1100 has a keeper circuit coupled to the wire, where the keeper circuit is operable to hold the wire at the first voltage level when the line driver presents the high impedance to the wire.

In some implementations, the master device and the slave device are configured to use the wire to exchange data provided in accordance with an RFFE protocol. Certain aspects of the RFFE protocol may be adapted to support 1-Wire communication. In some instances, data is exchanged in a pulse-width modulated signal transmitted over the wire.

The processor-readable storage medium 1118 may include transitory or non-transitory storage devices configured to store code, instructions and/or parameters used to implement one or more methods or procedures disclosed herein. The processor-readable storage medium 1118 may include code for driving a wire coupling a master device to a slave device from a first voltage level to a second voltage level, causing a line driver in the master device to present a high impedance to the wire after the wire has been driven to the second voltage level, determining that the slave device is communicating a first bit-value when the wire has been driven to the first voltage level before a threshold duration of time has elapsed, determining that the slave device is communicating a second bit-value when the wire is at the second voltage level after the threshold duration of time has elapsed, and driving the wire from the second voltage level to the first voltage level when the wire is at the second voltage level after a threshold duration of time has elapsed.

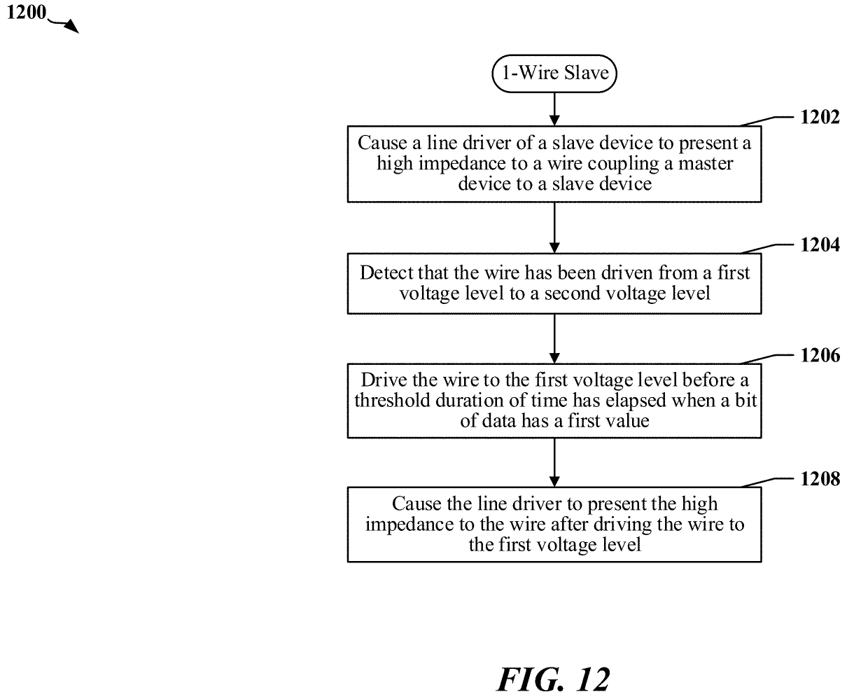

FIG. 12 is a flowchart 1200 of a method that may be performed by a one-wire slave device coupled to a serial bus. At least one bus master is coupled to the serial bus. One or more one-wire slave devices may be coupled to the serial bus. The master device may exchange PWM-encoded frames of data with the one-wire slave devices.

At block 1202, the one-wire slave device may cause a line driver of a slave device to present a high impedance to a wire coupling a master device to a slave device. At block 1204, the one-wire slave device may detect that the wire has been driven from a first voltage level to a second voltage level. At block 1206, the one-wire slave device may drive the wire to the first voltage level before a threshold duration of time has elapsed when a bit of data has a first value. At block 1208, the one-wire slave device may cause the line driver to present the high impedance to the wire after driving the wire to the first voltage level. The one-wire slave device may refrain from driving the wire during a bit transmission interval to signal a bit of data that has a second value.

In one example, the wire is driven by the master device to the second voltage level at the beginning of a bit transmission interval. In some instances, a first resistor may be coupled to the wire, and may hold the wire at the second voltage level after the wire is driven by the master device to the second voltage level. A second resistor coupled to the wire may hold the wire at the first voltage level after the wire is driven to the first voltage level. The first and second resistors may be coupled to the wire through switches that are controlled by a bus master. In some instances, a keeper circuit may be coupled to the wire and may be operable to hold the wire at the second voltage level after the wire is driven by the master device to the second voltage level. The keeper circuit is further operable to hold the wire at the first voltage level after the wire is driven to the first voltage level.

In various examples, the master device and the slave device are configured to use the wire to exchange data provided in accordance with an RFFE protocol. Certain aspects of the RFFE protocol may be adapted to support 1-Wire communication. In some instances, data is exchanged in a pulse-width modulated signal transmitted over the wire.

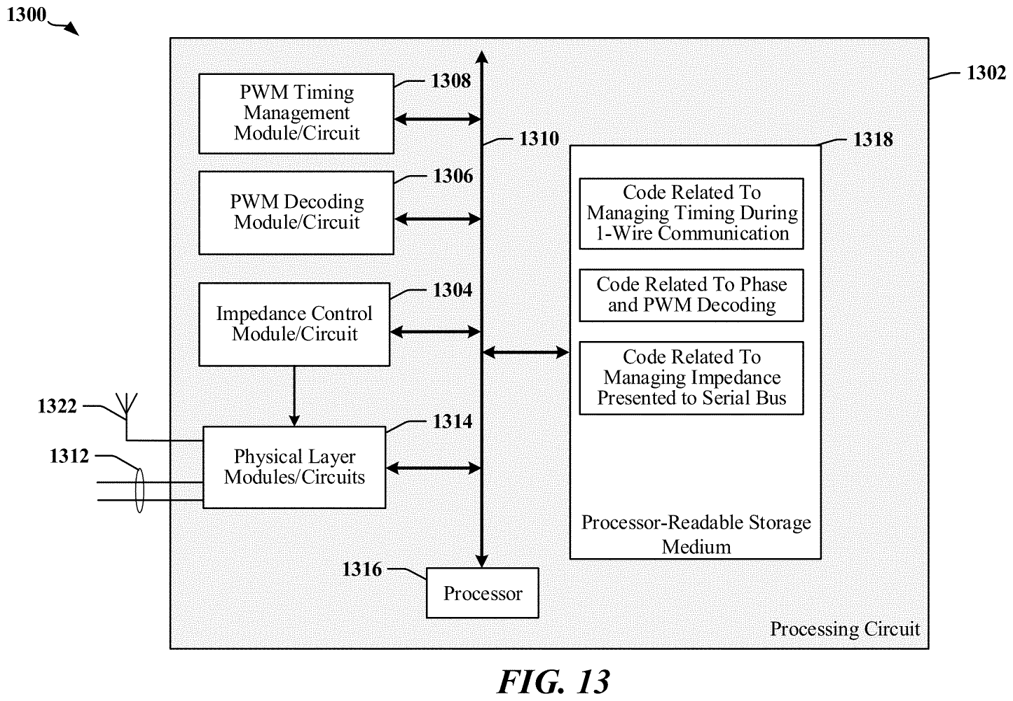

FIG. 13 is a diagram illustrating a simplified example of a hardware implementation for an apparatus 1300 employing a processing circuit 1302. The processing circuit typically has a controller or processor 1316 that may include one or more microprocessors, microcontrollers, digital signal processors, sequencers and/or state machines. The processing circuit 1302 may be implemented with a bus architecture, represented generally by the bus 1310. The bus 1310 may include any number of interconnecting buses and bridges depending on the specific application of the processing circuit 1302 and the overall design constraints. The bus 1310 links together various circuits including one or more processors and/or hardware modules, represented by the controller or processor 1316, the modules or circuits 1304, 1306 and 1308 and the processor-readable storage medium 1318. One or more physical layer circuits and/or modules 1314 may be provided to support communication over a communication link implemented using a multi-wire bus 1312, through an antenna or antenna array 1322 (to a radio access network for example), and so on. The bus 1310 may also link various other circuits such as timing sources, peripherals, voltage regulators, and power management circuits, which are well known in the art, and therefore, will not be described any further.

The processor 1316 is responsible for general processing, including the execution of software, code and/or instructions stored on the processor-readable storage medium 1318. The processor-readable storage medium 1318 may include a non-transitory storage medium. The software, when executed by the processor 1316, causes the processing circuit 1302 to perform the various functions described supra for any particular apparatus. The processor-readable storage medium 1318 may be used for storing data that is manipulated by the processor 1316 when executing software. The processing circuit 1302 further includes at least one of the modules 1304, 1306 and 1308. The modules 1304, 1306 and 1308 may be software modules running in the processor 1316, resident/stored in the processor-readable storage medium 1318, one or more hardware modules coupled to the processor 1316, or some combination thereof. The modules 1304, 1306 and 1308 may include microcontroller instructions, state machine configuration parameters, or some combination thereof.

In one configuration, the apparatus 1300 includes modules and/or circuits 1304 adapted to control impedance of a line driver coupled to a 1-Wire serial bus, including circuits that enable and disable the output of the line driver. The apparatus 1300 may include modules and/or circuits 1306 adapted to decode data from PWM datagrams, and modules and/or circuits 1308 adapted to manage timing associated with 1-Wire PWM transactions.

In one example, the apparatus 1300 includes physical layer circuits and/or modules 1314 that implement an interface circuit with a line driver adapted or configured to couple the apparatus 1300 to a serial bus. The apparatus 1300 may have a protocol controller configured to cause a line driver of a slave device to present a high impedance to a wire coupling a master device to a slave device, detect that the wire has been driven from a first voltage level to a second voltage level, drive the wire to the first voltage level before a threshold duration of time has elapsed when a bit of data has a first value, and cause the line driver to present the high impedance to the wire after driving the wire to the first voltage level. The wire may be driven by the master device to the second voltage level at the beginning of a bit transmission interval.

In certain implementations, the apparatus 1300 has a first resistor coupled to the wire holds the wire at the second voltage level after the wire is driven by the master device to the second voltage level. The apparatus 1300 has a second resistor coupled to the wire holds the wire at the first voltage level after the wire is driven to the first voltage level. In another example, a keeper circuit coupled to the wire is operable to hold the wire at the second voltage level after the wire is driven by the master device to the second voltage level. The keeper circuit is operable to hold the wire at the first voltage level after the wire is driven to the first voltage level.

In certain implementations, the master device and the slave device are configured to use the wire to exchange data provided in accordance with an RFFE protocol. Certain aspects of the RFFE protocol may be adapted to support 1-Wire communication. In some instances, data is exchanged in a pulse-width modulated signal transmitted over the wire.

The processor-readable storage medium 1318 may include transitory or non-transitory storage devices configured to store code, instructions and/or parameters used to implement one or more methods or procedures disclosed herein. The processor-readable storage medium 1318 may include code for causing a line driver of a slave device to present a high impedance to a wire coupling a master device to a slave device, detecting that the wire has been driven from a first voltage level to a second voltage level, driving the wire to the first voltage level before a threshold duration of time has elapsed when a bit of data has a first value, and causing the line driver to present the high impedance to the wire after driving the wire to the first voltage level.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A method of data communication performed at a master device, comprising:
driving a wire coupling the master device to a slave device from a first voltage level to a second voltage level;
causing a line driver in the master device to present a high impedance to the wire after the wire has been driven to the second voltage level;
determining that the slave device is communicating a first bit-value when the wire has been driven to the first voltage level before a threshold duration of time has elapsed;
determining that the slave device is communicating a second bit-value when the wire is at the second voltage level after the threshold duration of time has elapsed; and
driving the wire from the second voltage level to the first voltage level when the wire is at the second voltage level after the threshold duration of time has elapsed.

2. The method of claim 1, wherein the wire is driven by the master device to the second voltage level as a bit transmission interval begins.

3. The method of claim 1, further comprising:
coupling a first resistor to the wire prior to causing the line driver in the master device to present the high impedance to the wire, wherein the first resistor is configured to pull the wire to the second voltage level.

4. The method of claim 1, wherein a keeper circuit coupled to the wire is operable to hold the wire at the second voltage level after the line driver in the master device has been caused to present the high impedance to the wire.

5. The method of claim 1, further comprising:
detecting that the wire has been driven to the first voltage level before the threshold duration of time has elapsed; and
coupling a second resistor to the wire after detecting that the wire has been driven to the first voltage level, wherein the second resistor is configured to pull the wire to the first voltage level.

6. The method of claim 1, wherein a keeper circuit coupled to the wire is operable to hold the wire at the first voltage level when the wire is at the first voltage level.

7. The method of claim 1, wherein the master device and the slave device are configured to use the wire to exchange data provided in accordance with a radio frequency front end protocol.

8. The method of claim 7, wherein the data is exchanged in a pulse-width modulated signal transmitted over the wire.

9. A data communication apparatus, comprising:
a line driver configured to couple the apparatus to a wire of a serial bus; and
a protocol controller configured to:
cause the line driver to drive the wire from a first voltage level to a second voltage level as a bit transmission interval begins;
cause the line driver to present a high impedance to the wire after the wire has been driven to the second voltage level;
determine that a slave device is communicating a first bit-value when the wire has been driven to the first voltage level before a threshold duration of time has elapsed;
determine that the slave device is communicating a second bit-value when the wire is at the second voltage level after the threshold duration of time has elapsed; and
cause the line driver to drive the wire from the second voltage level to the first voltage level when the wire is at the second voltage level after the threshold duration of time has elapsed.

10. The apparatus of claim 9, further comprising:
a first resistor tied to the second voltage level,
wherein the protocol controller is further configured to couple the first resistor to the wire prior to causing the line driver to present the high impedance to the wire.

11. The apparatus of claim 9, further comprising:
a keeper circuit coupled to the wire, wherein the keeper circuit is operable to hold the wire at the second voltage level when the line driver presents the high impedance to the wire.

12. The apparatus of claim 9, further comprising:
a second resistor tied to the first voltage level, wherein the protocol controller is further configured to:
detect that the wire has been driven to the first voltage level before the threshold duration of time has elapsed; and
couple the second resistor to the wire prior to causing the line driver to present the high impedance to the wire.

13. The apparatus of claim 9, further comprising:
a keeper circuit coupled to the wire, wherein the keeper circuit is operable to hold the wire at the first voltage level when the wire is at the first voltage level.

14. The apparatus of claim 9, wherein the apparatus and the slave device are configured to use the wire to exchange data provided in accordance with a radio frequency front end protocol.

15. The apparatus of claim 14, wherein the data is exchanged in a pulse-width modulated signal transmitted over the wire.

16. A method of data communication, comprising:
causing a line driver of a slave device to present a high impedance to a wire coupling a master device to the slave device;
detecting that the wire has been driven from a first voltage level to a second voltage level;
driving the wire to the first voltage level before a threshold duration of time has elapsed when a bit of data has a first value; and
causing the line driver to present the high impedance to the wire after driving the wire to the first voltage level.

17. The method of claim 16, wherein the wire is driven by the master device to the second voltage level as a bit transmission interval begins.

18. The method of claim 17, wherein a first resistor coupled to the wire holds the wire at the second voltage level after the wire is driven by the master device to the second voltage level.

19. The method of claim 17, wherein a keeper circuit coupled to the wire is operable to hold the wire at the second voltage level after the wire is driven by the master device to the second voltage level.

20. The method of claim 16, wherein a second resistor coupled to the wire holds the wire at the first voltage level after the wire is driven to the first voltage level.

21. The method of claim 16, wherein a keeper circuit coupled to the wire is operable to hold the wire at the first voltage level after the wire is driven to the first voltage level.

22. The method of claim 16, wherein the master device and the slave device are configured to use the wire to exchange data provided in accordance with a radio frequency front end protocol.

23. The method of claim 22, wherein the data is exchanged in a pulse-width modulated signal transmitted over the wire.

24. A slave device comprising:
a line driver configured to couple the slave device to a wire of a serial bus; and
a protocol controller configured to:
cause the line driver to present a high impedance to the wire coupling a master device to the slave device;
detect that the wire has been driven from a first voltage level to a second voltage level;
drive the wire to the first voltage level before a threshold duration of time has elapsed when a bit of data has a first value; and
cause the line driver to present the high impedance to the wire after driving the wire to the first voltage level,
wherein the wire is driven by the master device to the second voltage level as a bit transmission interval begins.

25. The slave device of claim 24, wherein a first resistor coupled to the wire holds the wire at the second voltage level after the wire is driven by the master device to the second voltage level.

26. The slave device of claim 24, wherein a keeper circuit coupled to the wire is operable to hold the wire at the second voltage level after the wire is driven by the master device to the second voltage level.

27. The slave device of claim 24, wherein a second resistor coupled to the wire holds the wire at the first voltage level after the wire is driven to the first voltage level.

28. The slave device of claim 24, wherein a keeper circuit coupled to the wire is operable to hold the wire at the first voltage level after the wire is driven to the first voltage level.

29. The slave device of claim 24, wherein the master device and the slave device are configured to use the wire to exchange data provided in accordance with a radio frequency front end protocol.

30. The slave device of claim 29, wherein the data is exchanged in a pulse-width modulated signal transmitted over the wire.
